(19) United States
(12) Patent Application Publication
(10) Pub. No.: US 2020/0132768 A1
(43) Pub. Date: Apr. 30, 2020

(54) SAS Connector Conduction Detecting System And Method Thereof

(71) Applicants: Inventec (Pudong) Technology Corporation, Shanghai (CN); Inventec Corporation, Taipei City (TW)

(72) Inventor: Yuan Sang, Shanghai (CN)

(21) Appl. No.: 16/226,190

(22) Filed: Dec. 19, 2018

(30) Foreign Application Priority Data
Oct. 29, 2018 (CN) 201811268635.4

(51) Int. Cl. G01R 31/3185; G06F 11/22

(52) U.S. Cl. CPC G01R 31/318597; G06F 11/2221; G01R 31/318572

(57) ABSTRACT

A SAS connector conduction detecting system and a method thereof are provided. By a SAS connector on a detection circuit board and a mainboard SAS connector of a mainboard are connected to each other, and the detection circuit board and a test access port controller are connected in series with each other through a JTAG input connector and a JTAG output connector on the detection circuit board. The detection circuit board can provide the conduction detection for one mainboard SAS connector of the mainboard, thereby achieving the technical effect of improving the detection efficiency of the SAS connector.

### BACKGROUND OF THE INVENTION

### 1. Field of the Invention

The present invention generally relates to a detection system and a method thereof, more particularly to a SAS connector conduction detecting system and a method thereof by connecting a SAS connector on a detection circuit board to a mainboard SAS connector of a mainboard, and cascading a test access port (TAP) controller and the detection circuit board through a JTAG input connector and a JTAG output connector on the detection circuit board.

### 2. Description of the Related Art

The existing signal testing on the mainboard/SC SAS connector mainly uses the function test. Many dealers purchase a SAS test fixture to perform diagnosis by the high-speed differential communication between the SAS test fixture and the device under test. This test fixture is usually costly (it usually requires a more powerful MCU and peripheral circuits).

In summary, it can be seen that there is a problem in the prior art of excessive cost for a SAS connector detection. Therefore, it is necessary to propose an improved technical solution to solve this problem.

### SUMMARY OF THE INVENTION

In order to solve aforementioned problem in the prior art of excessive cost for a SAS connector detection, the present invention discloses a SAS connector conduction detecting system and a method thereof.

The SAS connector conduction detecting system of the present invention includes a mainboard and a detection circuit board. The mainboard includes a plurality of mainboard SAS connectors and a boundary scan chip. The detection circuit board includes a SAS connector, a JTAG input connector, a HAG output connector, a buffer, a complex programmable logic device (CPLD), a first JTAG chip, a second JTAG chip, a first multiplexer, a second multiplexer, a microprocessor, an electrically-erasable programmable read-only memory (EEPROM), an analog-to-digital converter (ADC), and a voltage regulator.

The boundary scan chip on the mainboard is electrically connected to the plurality of mainboard SAS connectors on the mainboard respectively.

The SAS connector is electrically connected to the CPLD, the first JTAG chip, the second JTAG chip, the ADC, and the voltage regulator respectively. The JTAG input connector is electrically connected to the JTAG output connector, the buffer, and the first multiplexer respectively. The JTAG output connector is electrically connected to the JTAG input connector and the first multiplexer respectively. The buffer is electrically connected to the JTAG input connector, the JTAG output connector, and the CPLD respectively. The CPLD is electrically connected to the buffer, the first JTAG chip, the SAS connector, and the microprocessor respectively. The first JTAG chip is electrically connected to the SAS connector, the CPLD, and the second JTAG chip respectively. The second JTAG chip is electrically connected to the SAS connector and the first JTAG chip respectively. The first multiplexer is electrically connected to the JTAG input connector, the JTAG output connector, the CPLD, and the microprocessor respectively. The second multiplexer is electrically connected to the microprocessor, the EEPROM, and the ADC respectively. The microprocessor is electrically connected to the CPLD, the first multiplexer, the second multiplexer, and the ADC respectively. The EEPROM is electrically connected to the second multiplexer. The ADC is electrically connected to the SAS connector, the second multiplexer, and the microprocessor respectively. The voltage regulator is electrically connected to the first multiplexer and a power source respectively. When the SAS connector of the detection circuit board is connected to one of the plurality of mainboard SAS connectors of the mainboard, the detection circuit board provides the conduction detection for the one of the plurality of mainboard SAS connectors of the mainboard.

The SAS connector conduction detecting method of the present invention includes the following steps of: providing a mainboard having a plurality of mainboard. SAS connectors and a boundary scan chip first; electrically connecting the boundary scan chip to the plurality of mainboard SAS connectors respectively; providing a detection circuit board having a SAS connector, a JTAG input connector, a JTAG output connector, a buffer, a CPLD, a first JTAG chip, a second JTAG chip, a first multiplexer, a second multiplexer, a microprocessor, an EEPROM, an ADC, and a voltage regulator; electrically connecting the SAS connector to the CPLD, the first JTAG chip, the second JTAG chip, the ADC, and the voltage regulator respectively; electrically connecting the JTAG input connector to the JTAG output connector, the buffer, and the first multiplexer respectively; electrically connecting the JTAG output connector to the JTAG input connector and the first multiplexer respectively; electrically connecting the buffer to the JTAG input connector, the JTAG output connector, and the CPLD respectively; electrically connecting the CPLD to the buffer, the first JTAG chip, the SAS connector, and the microprocessor respectively; electrically connecting the first JTAG chip to the SAS connector, the CPLD, and the second JTAG chip respectively; electrically connecting the second JTAG chip to the SAS connector and the first JTAG chip respectively; electrically connecting the first multiplexer to the JTAG input connector, the JTAG output connector, the CPLD, and the microprocessor respectively; electrically connecting the second multiplexer to the microprocessor, the EEPROM, and the ADC respectively; electrically connecting the microprocessor to the CPLD, the first multiplexer, the second multiplexer, and the ADC respectively; electrically connecting the EEPROM to the second multiplexer; electrically connecting the ADC to the SAS connector, the second multiplexer, and the microprocessor respectively; electrically connecting the voltage regulator to the first multiplexer and a power source respectively; and providing, by the detection circuit board, the conduction detection for one of the plurality of mainboard SAS connectors of the mainboard when connecting the SAS connector of the detection circuit board to the one of the plurality of mainboard. SAS connectors of the mainboard.

The system and method disclosed by the present invention are as above, and the difference from the prior art is that the SAS connector on the detection circuit board and one of the mainboard. SAS connectors of the mainboard are connected to each other, and a TAP controller and the detection circuit board are cascaded through the JTAG input connector and the JTAG output connector on the detection circuit board, so that the detection circuit board can provide conduction detection for one of plurality of mainboard SAS connectors of the mainboard.

By aforementioned technology means, the present invention can achieve the technical technical effect in improving the detection efficiency of the SAS connector.

### BRIEF DESCRIPTION OF THE DRAWINGS

The structure, operating principle and effects of the present invention will be described in detail by way of various embodiments which are illustrated in the accompanying drawings.

FIG. 1 is a block diagram of a SAS connector conduction detecting system according to the present invention.

FIG. 2A and FIG. 2B are flowcharts of a SAS connector conduction detecting method according to the present invention.

FIG. 3A to FIG. 3D are schematic views of a portion of the test blocks for AS connector conduction detection according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. It is to be understood that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be understood that, although the terms ‘first’; ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present invention. As used herein, the term “or” includes any and all combinations of one or more of the associated listed items.

It will be understood that when an element is referred to as being “on,” “connected to” or “coupled to” another element, it can be directly on, connected or coupled to the other element, or intervening elements may be present. In contrast, when an element is referred to as being “directly on,” “directly connected to” or “directly coupled to” another element, there are no intervening elements present.

In addition, unless explicitly described to the contrary, the word “comprise” and variations such as “comprises” or “comprising”, will be understood to imply the inclusion of stated elements but not the exclusion of any other elements.

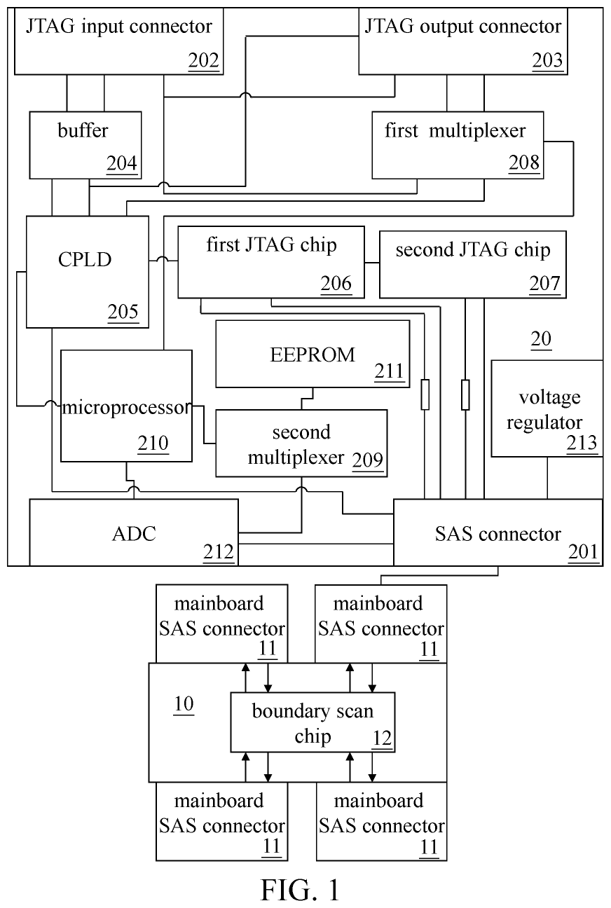

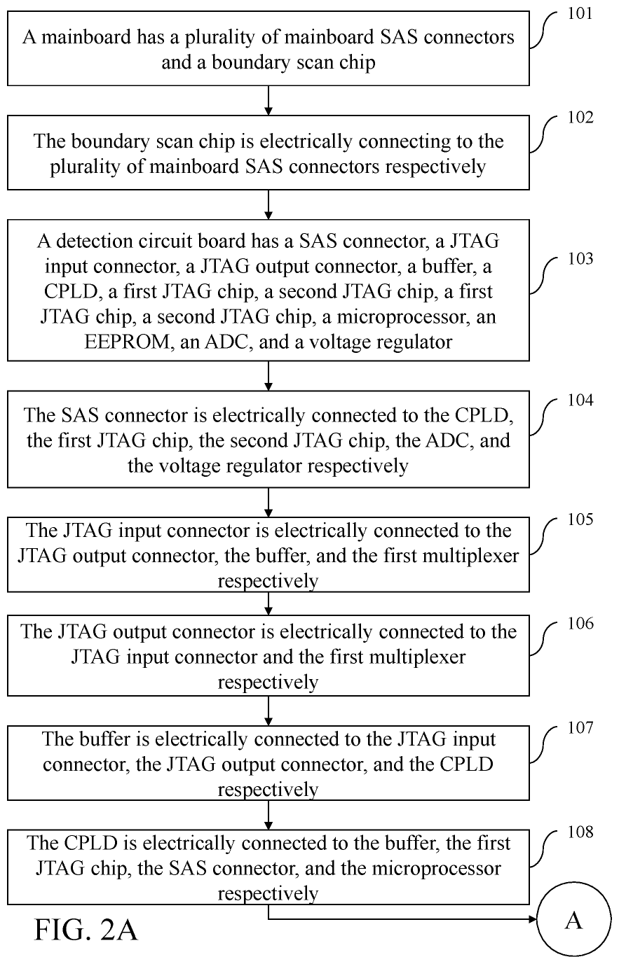

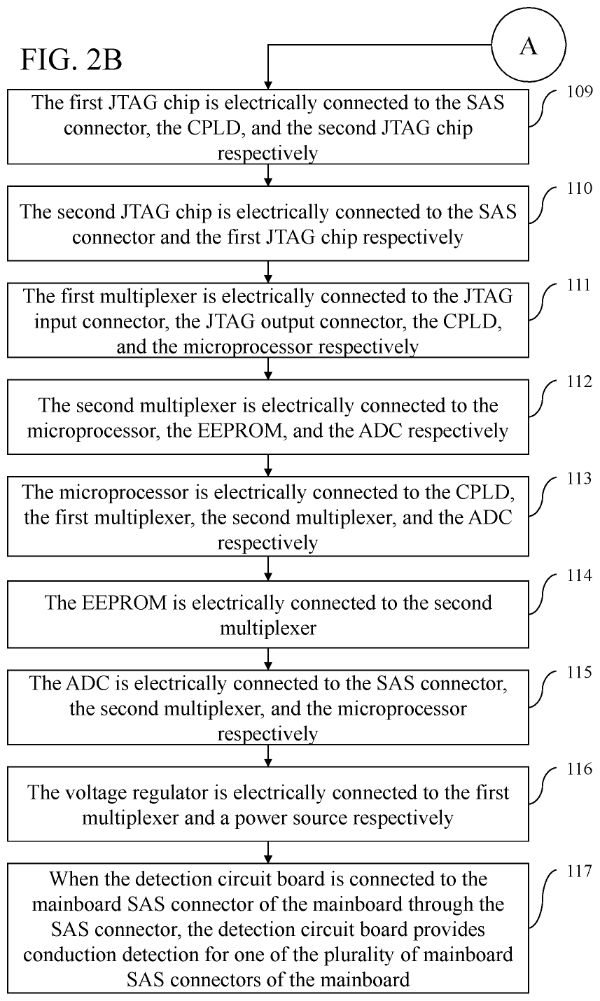

The operation of a SAS connector conduction detecting system of the present invention will be described below with reference to FIG. 1, FIG. 2A, and FIG. 2B, wherein FIG. 1 is a block diagram of a SAS connector conduction detecting system according to the present invention, and FIG. 2A and FIG. 2B are flowcharts of a SAS connector conduction detecting method according to the present invention.

The system of the present invention comprises a mainboard 10 and a detection circuit board 20. The mainboard 10 comprises a plurality of mainboard SAS connectors 11 and a boundary scan chip 12. That is, the mainboard 10 has a plurality of mainboard SAS connectors 11 and a boundary scan chip 12 (step 101). The boundary scan chip 12 is electrically connected to the plurality of mainboard SAS connector 11 respectively (step 102). The detection circuit board 20 comprises a SAS connector 201, a JTAG input connector 202, a JTAG output connector 203, a buffer 204, a CPLD 205, a first JTAG chip 206, a second JTAG chip 207, a first multiplexer 208, a second multiplexer 209, a microprocessor 210, an EEPROM 211, an ADC 212, and a voltage regulator 213. That is, the detection circuit board 20 has a SAS connector 201, a JTAG input connector 202, a JTAG output connector 203, a buffer 204, a CPLD 205, a first JTAG chip 206, a second JTAG chip 207, a first multiplexer 208, a second multiplexer 209, a microprocessor 210, an EEPROM 211, an ADC 212, and a voltage regulator 213 (step 103).

The SAS connector 201 of the detection circuit board 20 is electrically connected to the CPLD 205 of the detection circuit board 20, the first JTAG chip 206 of the detection circuit board 20, the second JTAG chip 207 of the detection circuit board 20, the ADC 212 of the detection circuit board 20, and the voltage regulator 213 of the detection circuit board 20 respectively (step 104).

The JTAG input connector 202 of the detection circuit board 20 is electrically connected to the JTAG output connector 203 of the detection circuit board 20, the buffer 204 of the detection circuit board 20, and the first multiplexer 208 of the detection circuit board 20 respectively (step 105).

The JTAG output connector 203 of the detection circuit board 20 is electrically connected to the JTAG input connector 202 of the detection circuit board 20 and the first multiplexer 208 of the detection circuit board 20 respectively (step 106).

The buffer 204 of the detection circuit board 20 is electrically connected to the JTAG input connector 202 of the detection circuit board 20, the JTAG output connector 203 of the detection circuit board 20, and the CPLD 205 of the detection circuit board 20 respectively (step 107).

The CPLD 205 of the detection circuit board 20 is electrically connected to the buffer 204 of the detection circuit board 20, the first JTAG chip 206 of the detection circuit board 20, the SAS connector 201 of the detection circuit board 20, and the microprocessor 210 of the detection circuit board 20 respectively (step 108).

The first JTAG chip 206 of the detection circuit board 20 is electrically connected to the SAS connector 201, the CPLD 205 of the detection circuit board 20, and the second JTAG chip 207 of the detection circuit board 20 respectively (step 109).

The second JTAG chip 207 of the detection circuit board 20 is electrically connected to the SAS connector 201 of the detection circuit board 20 and the first JTAG chip 206 of the detection circuit board 20 respectively (step 110).

The first multiplexer 208 of the detection circuit board 20 is electrically connected to the JTAG input connector 202 of the detection circuit board 20, the JTAG output connector 203 of the detection circuit board 20, the CPLD 205 of the detection circuit board 20, and the microprocessor 210 respectively (step 111).

The second multiplexer 209 of the detection circuit board 20 is electrically connected to the microprocessor 210, the EEPROM 211 of the detection circuit board 20, and the ADC 212 of the detection circuit board 20 respectively (step 112).

The microprocessor 210 of the detection circuit board 20 is electrically connected to the CPLD 205 of the detection circuit board 20, the first multiplexer 208 of the detection circuit board 20, the second multiplexer 209 of the detection circuit board 20, and the ADC 212 of the detection circuit board 20 respectively (step 113).

The EEPROM 211 of the detection circuit board 20 is electrically connected to the second multiplexer 209 of the detection circuit board 20 (step 114).

The ADC 212 of the detection circuit board 20 is electrically connected to the SAS connector 201 of the detection circuit board 20, the second multiplexer 209 of the detection circuit board 20, and the microprocessor 210 of the detection circuit board 20 respectively (step 115).

The voltage regulator 213 of the detection circuit board 20 is electrically connected to the first multiplexer 208 of the detection circuit board 20 and a power source respectively (step 116).

The CPLD 205 of the detection circuit board 20 can be implemented by using a chip whose model number is EPM240. The first JTAG chip 206 of the detection circuit board 20 can be implemented by using a chip whose model number is SCAN15MB200TSQ. The second JTAG chip 207 of the detection circuit board 20 can be implemented by using a chip whose model number is SCAN15MB200TSQ. The first multiplexer 208 of the detection circuit board 20 can be implemented by using a chip whose model number is 74CBTLV3257, and the second multiplexer 209 of the detection circuit board 20 can be implemented by using a chip whose model number is PCA9548. The microprocessor 210 of the detection circuit board 20 can be implemented by using a chip whose model number is LPC1113FBD48. The EEPROM 211 of the detection circuit board 20 can be implemented by using a chip whose model number is 24LC32AT. The ADC 212 of the detection circuit board 20 can be implemented by using a chip whose model number is MAX1039. The voltage regulator 213 of the detection circuit board 20 can be implemented by using a chip whose model number is IR3842. These are for illustrative purposes only and are not intended to limit the scope of application of the present invention.

The first JTAG chip 206 of the detection circuit board 20 and the second JTAG chip 207 of the detection circuit board 20 are provided to generate a differential detection signal and an input/output signal respectively. The microprocessor 210 of the detection circuit board 20 is used to control the first JTAG chip 206 of the detection circuit board 20 or the second JTAG chip 207 of the detection circuit board 20 to generate the input/output signal and is used to control the switching of integrated circuit bus signals.

The boundary scan chip 12 on the mainboard 10 is electrically connected to the mainboard SAS connectors 11 on the mainboard 10 respectively. The JTAG input connector 202 of the detection circuit board 20 can be electrically connected to a TAP controller or the JTAG output connector 202 of another detection circuit board 20. The JTAG output connector 203 of the detection circuit board 20 is electrically connected to the JTAG input connector 202 of the other detection circuit board 20 or is unconnected. When one of the plurality of mainboard SAS connectors 11 of the mainboard 10 is connected to the SAS connector 201 of the detection circuit board 20, the TAP controller provides a detection signal to the detection circuit board 20, and the conduction detection of the connector pins is performed on the one of the plurality of mainboard SAS connectors 11 of the mainboard 10 and the SAS connector 201 of the detection circuit board 20 according to the detection signal (step 117).

Each of the plurality of mainboard SAS connectors 11 of the mainboard 10 and the SAS connector 201 of the detection circuit board 20 include integrated circuit buses, input/output pins, ground pins, data transfer pins, and analog signal pins respectively. This is for illustrative purposes only and is not intended to limit the scope of application of the present invention. That is, the detection signal is used to detect conduction including differential signal pin detection, ground signal pin detection, analog signal pin detection, input/output pin detection, and integrated circuit bus pin detection on the mainboard SAS connector 11 of the mainboard 10.

When the conduction detection of the pins of the mainboard SAS connector 11 of the mainboard 10 is performed, the TAP controller sets the boundary scan chip 12 of the mainboard 10, the CPLD 205 of the detection circuit board 20, the first JTAG chip 206 of the detection circuit board 20 and the second JTAG chip 207 of the detection circuit board 20 to be in the boundary scan mode.

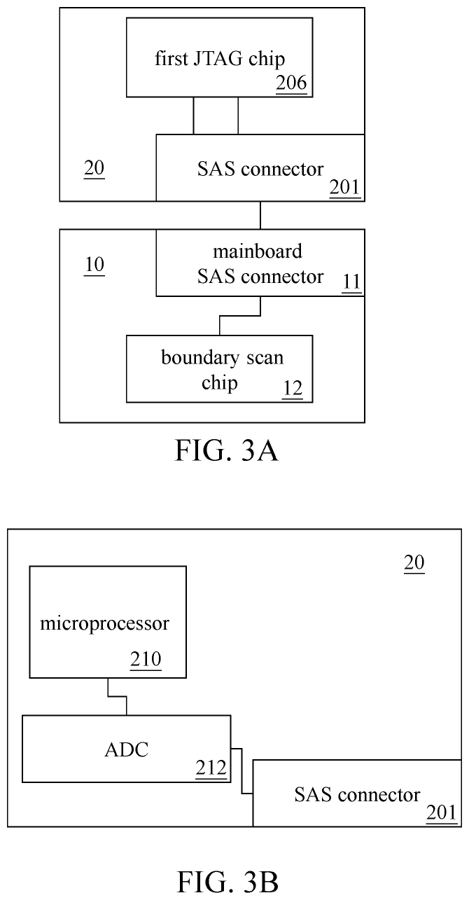

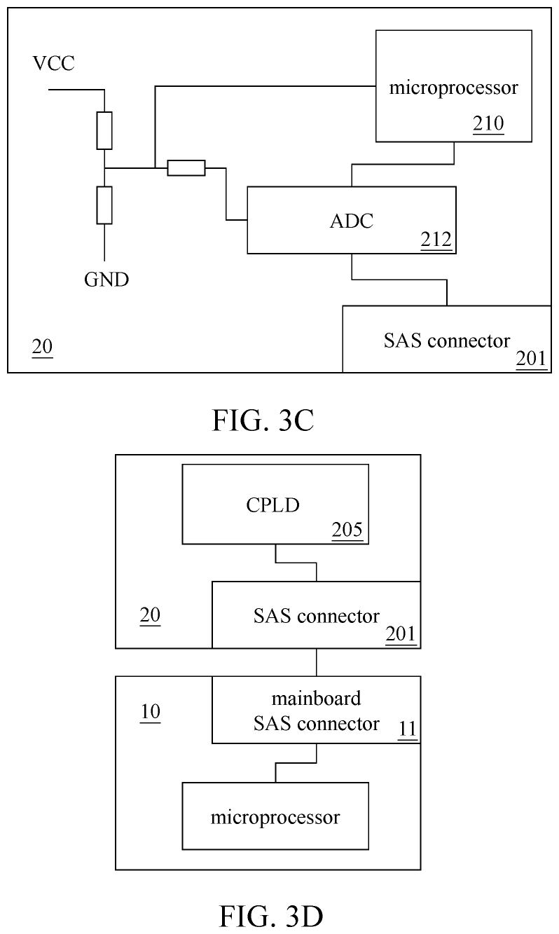

Please refer to FIG. 3A, and FIG. 3A is a schematic view of a portion of the test blocks for SAS connector conduction detection according to the present invention.

The boundary scan chip 12 of the mainboard 10, the CPLD 205 of the detection circuit board 20, the first JTAG chip 206 of the detection circuit board 20, the second JTAG chip 207 of the detection circuit board 20, and the microprocessor 210 of the detection circuit board 20 generate a differential signal or perform signal control according to the detection signal.

In the signal detection of the TX_DP pin (that is, the data transfer pin) and the TX_DN pin (that is, the data transfer pin) in the mainboard SAS connector 11, the differential signal is generated by the first JTAG chip 206 or the second JTAG chip 207 of the detection circuit board 20, and is transmitted to the boundary scan chip 12 of the mainboard 10 through the SAS connector 201 of detection circuit board 20 and the mainboard SAS connector 11 of the mainboard 10 for detection when the first JTAG chip 206 or the second. JTAG chip 207 of the detection circuit board 20 receives the detection signal.

If the differential signal sent by the first JTAG chip 206 or the second JTAG chip 207 of the detection circuit board 20 coincides with the differential signal received by the boundary scan chip 12 of the mainboard 10, the conduction detection of the TX_DP pin and the TX_DN pin in the mainboard SAS connector 11 passes. Conversely, if the differential signal sent by the first JTAG chip 206 or the second JTAG chip 207 of the detection circuit board 20 does not coincide with the differential signal received by the boundary scan chip 12 of the mainboard 10, the conduction detection of the TX_DP pin and the TX_DN pin in the mainboard SAS connector 11 fails.

In the signal detection of the RX_DP pin (that is, the data transfer pin) and the RX_DN pin (that is, the data transfer pin) in the mainboard. SAS connector 11, the differential signal is generated by the boundary scan chip 12 of the mainboard 10, and is transmitted to the first JTAG chip 206 or the second JTAG chip 207 of the detection circuit board 20 through the SAS connector 201 of detection circuit board 20 and the mainboard SAS connector 11 of the mainboard 10 for detection when the boundary scan chip 12 of the mainboard 10 receives the detection signal.

If the differential signal sent by the boundary scan chip 12 of the mainboard 10 coincides with the differential signal received by the first JTAG chip 206 or the second JTAG chip 207 of the detection circuit board 20, the conduction detection of the RX_DP pin and the RX_DN pin in the mainboard. SAS connector 11 passes. Conversely, if the differential signal sent by the boundary scan chip 12 of the mainboard 10 does not coincide with the differential signal received by the first JTAG chip 206 or the second. JTAG chip 207 of the detection circuit board 20, the conduction detection of the RX_DP pin and the RX_DN pin in the mainboard SAS connector 11 fails.

Please refer to FIG. 3B and FIG. 3C, and FIG. 3B and FIG. 3C are schematic views of a portion of the test blocks for SAS connector conduction detection according to the present invention

The signal detection of the analog signal pins in the mainboard SAS connector 11 comprises the following steps. When the microprocessor 210 of the detection circuit board 20 receives the detection signal, the microprocessor 210 of the detection circuit board 20 is connected to the ADC 212 of the detection circuit board 20 through the integrated circuit bus. After the ADC 212 of the detection circuit board 20 reads the voltage value of the analog signal pins in the mainboard SAS connector 11, the microprocessor 210 of the detection circuit board 20 stores the voltage value of the analog signal pins in the mainboard SAS connector 11 read by the ADC 212 of the detection circuit board 20, and the microprocessor 210 of the detection circuit board 20 determines whether the detection result is correct according to the voltage value, thereby determining whether the analog signal pins in the mainboard SAS connector 11 are conductive.

It is worth noting that when the power source is open, the analog signal pins of the ADC 212 are in a null state, and the voltage of the analog signal pins of the ADC 212 is not in the steady state. In order to avoid the unstable voltage of the analog signal pins of the ADC 212, which are in the null state at the time of signal detection, pull-down resistors are connected to the analog signal pins of the ADC 212 respectively if there is no pull-down resistor connected to the analog signal pins of the ADC 212. The aforementioned pull-down resistor may have a resistance value ranging from 3 M ohms to 4 M ohms, which is merely illustrative and is not intended to limit the scope of application of the present invention.

Further, a resistive divider circuit is connected to the microprocessor 210 of the detection circuit board 20 and the ADC 212 of the detection circuit board 20 respectively. For example, the resistive divider circuit comprises 10 M ohms resistor and 2 M ohms resistor connected in series, which is merely illustrative here, and is not limited to the scope of application of the present invention. A backup line can be disposed between the resistive divider circuit and the ADC 212 of the detection board 20. That is, a 0-ohm resistor is connected in series between the resistive divider circuit and the ADC 212 of the detection board 20, as described in FIG. 3C.

Please refer to FIG. 3D, and FIG. 3D is a schematic view of a portion of the test blocks for SAS connector conduction detection according to the present invention.

In the signal detection of the input/output pins in the mainboard SAS connector 11, the input/output pins of the mainboard SAS connector 11 are connected to the CPLD 205 of the detection circuit board 20 and the microprocessor of the mainboard 10 respectively, and the microprocessor of the mainboard 10 is also a boundary scan chip. The CPLD 205 of the detection circuit board 20 sends the detection data to the microprocessor of the mainboard 10 according to the detection signal, and reads the input/output data of the input/output pins of the microprocessor of the mainboard 10 through the FT. If the input/output data sent by the CPLD 205 of the detection circuit board 20 is the same as the input/output data read by the FT from the microprocessor of the mainboard 10, the signal detection of the input/output pins in the mainboard SAS connector 11 passes. Conversely, if the input/output data sent by the CPLD 205 of the detection circuit board 20 is not the same as the input/output data read by the FT from the microprocessor of the mainboard 10, the signal detection of the input/output pins in the mainboard SAS connector 11 fails.

It is worth noting that the microprocessor of the mainboard 10 is also a boundary scan chip, but the microprocessor of the mainboard 10 determines that the JTAG function is enable or disable according to the firmware of the mainboard. The microprocessor of the motherboard 10 has only the input/output pins set to be enable, which is merely illustrative here, and is not limited to the application scope of the present invention.

In summary, it can be seen that the difference between the present invention and the prior art is that the SAS connector on the detection circuit board and the mainboard SAS connector of the mainboard are connected to each other, and the detection circuit board and the TAP controller are connected in series with each other through the JTAG input connector and the JTAG output connector on the detection circuit board, so that the detection circuit board can provide conduction detection for one mainboard SAS connector of the mainboard.

Above-mentioned technical means can be used to solve the problem of excessive cost for a SAS connector detection in the prior art, so as to achieve the technical effect of improving the detection efficiency of the SAS connector.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A SAS connector conduction detecting system, comprising:
a mainboard, comprising:
a plurality of mainboard SAS connectors; and
a boundary scan chip; wherein the boundary scan chip is electrically connected to the mainboard SAS connectors respectively;
a detection circuit board, comprising a SAS connector, a JTAG input connector, a JTAG output connector; a buffer, a complex programmable logic device (CPLD), a first a JTAG chip, a second JTAG chip, a first multiplexer, a second multiplexer, a microprocessor, an electrically-erasable programmable read-only memory (EEPROM); an analog-to-digital converter (ADC); and a voltage regulator, wherein:
the SAS connector is electrically connected to the CPLD, the first JTAG chip, the second JTAG chip; the ADC, and the voltage regulator respectively;
the JTAG input connector is electrically connected to the JTAG output connector; the buffer, and the first multiplexer respectively;
the JTAG output connector is electrically connected to the JTAG input connector and the first multiplexer respectively;
the buffer is electrically connected to the JTAG input connector, the JTAG output connector; and the CPLD respectively;
the CPLD is electrically connected to the buffer, the first JTAG chip, the SAS connector; and the microprocessor respectively;
the first JTAG chip is electrically connected to the SAS connector, the CPLD, and the second JTAG chip respectively;
the second JTAG chip is electrically connected to the SAS connector and the first JTAG chip respectively;
the first multiplexer is electrically connected to the JTAG input connector, the JTAG output connector, the CPLD; and the microprocessor respectively;
the second multiplexer is electrically connected to the microprocessor, the EEPROM, and the ADC respectively;
the microprocessor is electrically connected to the CPLD, the first multiplexer, the second multiplexer, and the ADC respectively;
the EEPROM is electrically connected to the second multiplexer;
the ADC is electrically connected to the SAS connector, the second multiplexer, and the microprocessor respectively;
the voltage regulator is electrically connected to the first multiplexer and a power source respectively; and
when the detection circuit board is connected to one of the plurality of mainboard SAS connectors of the mainboard through the SAS connector, the detection circuit board provides conduction detection for the one of the plurality of mainboard SAS connectors of the mainboard.

2. The system according to claim 1, wherein the JTAG input connector of the detection circuit board is electrically connected to a test access port (TAP) controller or the JTAG output connector of another detection circuit board; and the JTAG output connector of the detection circuit board is electrically connected to the JTAG input connector of the other detection circuit board.

3. The system according to claim 1, wherein each of the plurality of mainboard SAS connector and the SAS connector comprise integrated circuit buses, input/output pins, ground pins, data transfer pins, and analog signal pins respectively.

4. The system according to claim 1, wherein the conduction detection of each of the plurality of mainboard SAS connectors comprises data transfer pin detection, analog signal pin detection, and input/output signal pin detection.

5. The system according to claim 1, wherein the CPLD and the microprocessor are set to be in a boundary scan mode by a TAP controller.

6. A conduction detecting method for a SAS connector, comprising:
providing a mainboard having a plurality of mainboard SAS connectors and a boundary scan chip;
electrically connecting the boundary scan chip to the plurality of mainboard SAS connectors respectively;
provided a detection circuit board having a SAS connector, a JTAG input connector; a JTAG output connector, a buffer, a CPLD, a first JTAG chip; a second JTAG chip; a first JTAG chip, a second JTAG chip, a microprocessor, an EEPROM; an ADC, and a voltage regulator, wherein:
the SAS connector is electrically connected to the CPLD; the first JTAG chip, the second JTAG chip, the ADC; and the voltage regulator respectively;
the JTAG input connector is electrically connected to the JTAG output connector, the buffer, and the first multiplexer respectively;
the JTAG output connector is electrically connected to the JTAG input connector and the first multiplexer respectively;
the buffer is electrically connected to the JTAG input connector, the JTAG output connector, and the CPLD respectively;
the CPLD is electrically connected to the buffer; the first JTAG chip, the SAS connector, and the microprocessor respectively;
the first JTAG chip is electrically connected to the SAS connector, the CPLD, and the second JTAG chip respectively;
the second JTAG chip is electrically connected to the SAS connector and the first JTAG chip respectively;
the first multiplexer is electrically connected to the JTAG input connector, the JTAG output connector, the CPLD, and the microprocessor respectively;
the second multiplexer is electrically connected to the microprocessor, the EEPROM, and the ADC respectively;
the microprocessor is electrically connected to the CPLD, the first multiplexer; the second multiplexer, and the ADC respectively;
the EEPROM is electrically connected to the second multiplexer;
the ADC is electrically connected to the SAS connector, the second multiplexer, and the microprocessor respectively;
the voltage regulator is electrically connected to the first multiplexer and a power source respectively; and
when the detection circuit board is connected to the mainboard SAS connector of the mainboard through the SAS connector, the detection circuit board provides conduction detection for one of the plurality of mainboard SAS connectors of the mainboard.

7. The method according to claim 6, wherein the JTAG input connector of the detection circuit board is electrically connected to a TAP controller or the JTAG output connector of another detection circuit board; and the JTAG output connector of the detection circuit board is electrically connected to the JTAG input connector of the other detection circuit board.

8. The method according to claim 6, wherein each of the plurality of mainboard SAS connector and the SAS connector comprise integrated circuit buses, input/output pins, ground pins, data transfer pins, and analog signal pins respectively.

9. The method according to claim 6, wherein the conduction detection of each of the plurality of mainboard SAS connectors comprises data transfer pin detection, analog signal pin detection, and input/output signal pin detection.

10. The method according to claim 6, wherein the CPLD and the microprocessor are set to be in a boundary scan mode by a TAP controller.
